(19) United States
(12) Patent Application Publication
(10) Pub. No.: US 2022/0124937 A1
(43) Pub. Date: Apr. 21, 2022

(54) HEAT DISSIPATION DEVICE

(71) Applicant: Acer Incorporated, New Taipei City (TW)

(72) Inventors: Shu-Hao Kuo, New Taipei City (TW); Wen-Neng Liao, New Taipei City (TW); Cheng-Wen Hsieh, New Taipei City (TW); Tsung-Ting Chen, New Taipei City (TW); Chun-Chieh Wang, New Taipei City (TW); Chi-Tai Ho, New Taipei City (TW); Kuan-Lin Chen, New Taipei City (TW)

(73) Assignee: Acer Incorporated, New Taipei City (TW)

(21) Appl. No.: 17/505,602

(22) Filed: Oct. 19, 2021

(30) Foreign Application Priority Data
Oct. 21, 2020 (TW) 109136560
May 20, 2021 (TW) 110205802

(51) Int. Cl. H05K 7/20

(52) U.S. Cl. CPC H05K 7/2039; H05K 7/20136

(57) ABSTRACT

A heat dissipation device includes a heat dissipation member and a fan. The heat dissipation member includes a first heat dissipation fin group and a second heat dissipation fin group stacked on the first heat dissipation fin group. The first heat dissipation fin group includes a plurality of first heat dissipation fins, and the second heat dissipation fin group includes a plurality of second heat dissipation fins. The fan is stacked on the second heat dissipation fin group. The fan is configured to rotate around an axis. The first heat dissipation fins and the second heat dissipation fins are arranged around the axis.

### CROSS-REFERENCE TO RELATED APPLICATION

This application claims the priority benefits of Taiwanese application no. 109136560, filed on Oct. 21, 2020 and Taiwanese application no. 110205802, filed on May 20, 2021. The entirety of each of the above-mentioned patent applications is hereby incorporated by reference herein and made a part of this specification.

### BACKGROUND

### Technical Field

The disclosure relates to a heat dissipation device, and more particularly, to a heat dissipation device adopting a double-layer heat dissipation fin group.

### Description of Related Art

As computing performance of an electronic component (e.g., a chip, a processor, or a controller) increases, heat generated during operation of the electronic component also increases. If the heat cannot be quickly dissipated to the outside, the computing performance of the electronic component may decline, or the electronic component may be disabled because of overheating. Therefore, relevant manufacturers all proactively invest in the development and improvement of heat dissipation devices in various forms to increase the heat dissipation efficiency.

A common heat dissipation device include a fan and a heat dissipation fin group, in which the fan is stacked on the heat dissipation fin group, and the heat dissipation fin group is thermally coupled to a heat source. Generally speaking, a single-layer design is adopted for the heat dissipation fin group. That is, the heat dissipation fin group includes a plurality of heat dissipation fins arranged at the same height. Therefore, space for air to flow in is not sufficient, and a heat dissipation area is also insufficient, resulting in adversely affected heat dissipation efficiency. In addition, the airflow caused during operation of the fan may flow through the heat dissipation fins for heat exchange. The number and the spacing of arrangement of the heat dissipation fins may affect the heat dissipation area and flow resistance. Moreover, excessive noise may be caused during operation of the fan.

### SUMMARY

The disclosure provides a heat dissipation device, in which heat dissipation efficiency is improved.

The disclosure provides a heat dissipation device. The heat dissipation device includes a heat dissipation member and a fan. The heat dissipation member includes a first heat dissipation fin group and a second heat dissipation fin group stacked on the first heat dissipation fin group. The first heat dissipation fin group includes a plurality of first heat dissipation fins, and the second heat dissipation fin group includes a plurality of second heat dissipation fins. The fan is stacked on the second heat dissipation fin group. The fan is configured to rotate around an axis. The first heat dissipation fins and the second heat dissipation fins are arranged around the axis.

Based on the foregoing, in the heat dissipation device according to an embodiment of the disclosure, the heat dissipation member is thermally coupled to the heat source. In the heat dissipation member, since the first heat dissipation fin group is closer to the heat source than the second heat dissipation fin group is, and the size of the first heat dissipation fin group is smaller than the size of the second heat dissipation fin group, an airflow may flow in the peripheral space of the first heat dissipation fin group to enhance convection and increase heat dissipation efficiency. On the other hand, since the second heat dissipation fin group is closer to the fan than the first heat dissipation fin group is, and the size of the second heat dissipation fin group is greater than the size of the first heat dissipation fin group, the second heat dissipation fin group may provide a greater heat exchange area or heat dissipation area to increase the heat dissipation efficiency.

In the heat dissipation device according to another embodiment of the disclosure, the second heat dissipation fin group is closer to the fan than the first heat dissipation fin group is, and the arrangement of the plurality of second heat dissipation fins in the second heat dissipation fin group is sparser than the arrangement of the plurality of first heat dissipation fins in the first heat dissipation fin group. Therefore, the airflow caused during operation of the fan may quickly flow through the second heat dissipation fin group and flow toward the first heat dissipation fin group. Moreover, the first heat dissipation fin group may provide a greater heat dissipation area, thereby increasing the flow efficiency and heat dissipation efficiency.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic side view of a heat dissipation device mounted on a circuit board according to an embodiment of the disclosure.

FIG. 2 is a schematic view of the heat dissipation device of FIG. 1.

FIG. 3A to FIG. 3C are schematic views of the heat dissipation member of FIG. 2 in three different perspectives.

FIG. 4A is a schematic enlarged view of a region R1 of FIG. 3A.

FIG. 4B is a schematic enlarged view of a region R2 of FIG. 3B.

FIG. 5 is a schematic diagram of a heat dissipation device according to another embodiment of the disclosure.

FIG. 6A and FIG. 6B are schematic views of the heat dissipation member of FIG. 5 in two different perspectives.

FIG. 6C is a schematic enlarged view of a region R3 of FIG. 6A.

FIG. 6D is a schematic enlarged view of a region R4 of FIG. 6B.

### DESCRIPTION OF THE EMBODIMENTS

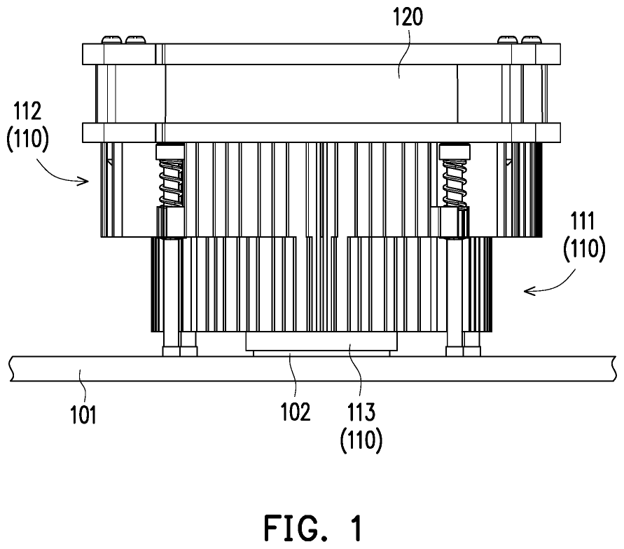

FIG. 1 is a schematic side view of a heat dissipation device mounted on a circuit board according to an embodiment of the disclosure. With reference to FIG. 1, in this embodiment, a heat dissipation device 100 may be an air-cooled heat dissipation device, and the heat dissipation device 100 includes a heat dissipation member 110 and a fan 120. The heat dissipation device 100 is mounted inside a computer host, a server, or other electronic devices to quickly discharge heat generated by a heat source 102 to the outside.

Further, the heat dissipation member 110 is mounted on a circuit board 101, and is thermally coupled to the heat source 102 on the circuit board 101. For example, the heat source 102 may be a central processing unit or a graphics processing unit, or other electronic components that generate heat during operation. On the other hand, the fan 120 may be an axial fan, and the fan 120 is mounted at one end of the heat dissipation member 110 away from the heat source 102. That is, the heat dissipation member 110 is located between the fan 120 and the heat source 102, and the heat source 102 is located between the heat dissipation member 110 and the circuit board 101.

Heat generated by the heat source 102 may be conducted to the heat dissipation member 110, while heat may be exchanged between an airflow caused during operation of the fan 120 and the heat dissipation member 110, eventually discharging the heat to the outside. To increase the heat exchange area or heat dissipation area, the heat dissipation member 110 is formed of a first heat dissipation fin group 111 and a second heat dissipation fin group 112. The first heat dissipation fin group 111 is close to the heat source 102, and the second heat dissipation fin group 112 is stacked on the first heat dissipation fin group 111. On the other hand, the fan 120 is stacked on the second heat dissipation fin group 112, which is to say, the fan 120 is mounted on the second heat dissipation fin group 112. In other words, the first heat dissipation fin group 111 is located between the second heat dissipation fin group 112 and the heat source 102, and the second heat dissipation fin group 112 is located between the fan 120 and the first heat dissipation fin group 111.

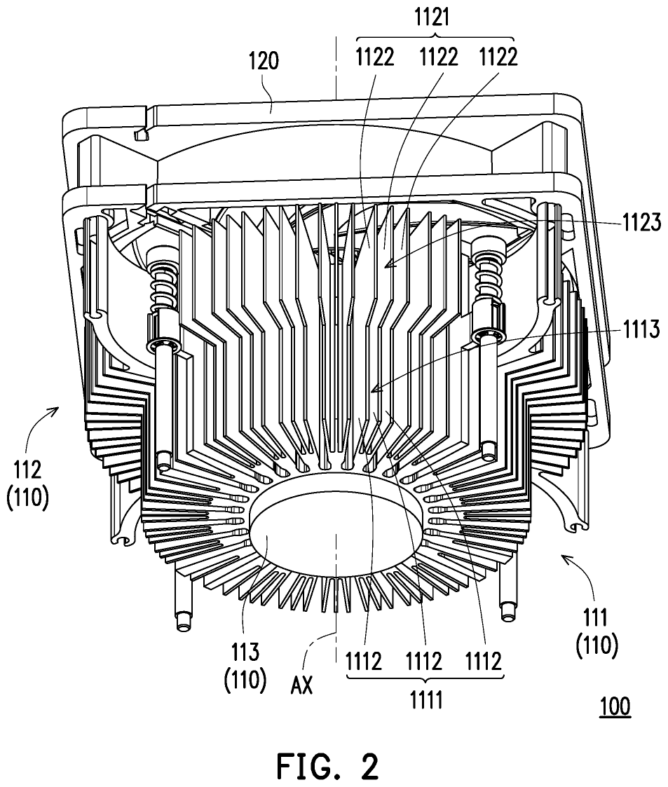

FIG. 2 is a schematic view of the heat dissipation device of FIG. 1. With reference to FIG. 1 and FIG. 2, in this embodiment, the heat dissipation member 110 is an aluminum extrusion structure and is mechanically cut. In terms of the manufacturing process, an aluminum ingot is first heated to a temperature at which the aluminum ingot is moldable, and then pressurized and extruded through a mold. As a result, a prototype of the heat dissipation fin group is produced, and the prototype of heat dissipation fin group has not been divided into the first heat dissipation fin group 111 and the second heat dissipation fin group 112 with a difference in size. Afterwards, the prototype of the heat dissipation fin group was mechanically cut to remove a part thereof in the circumferential direction to produce the first heat dissipation fin group 111 and the second heat dissipation fin group 112 with a difference in size. In addition, the size of the first heat dissipation fin group 111 is smaller than the size of the second heat dissipation fin group 112.

The size of the first heat dissipation fin group 111 may refer to the volume, area, or radial length. Correspondingly, the size of the second heat dissipation fin group 112 may refer to the volume, area, or radial length. Since the second heat dissipation fin group 112 is closer to the fan 120 than the first heat dissipation fin group 111 is, and the size of the second heat dissipation fin group 112 is greater than the size of the first heat dissipation fin group 111, the second heat dissipation fin group 112 may provide a greater heat exchange area or heat dissipation area to increase heat dissipation efficiency.

On the other hand, since the first heat dissipation fin group 111 is closer to the heat source 102 than the second heat dissipation fin group 112 is, and the size of the first heat dissipation fin group 111 is smaller than the size of the second heat dissipation fin group 112, an airflow may flow in the peripheral space of the first heat dissipation fin group 111 to enhance convection and increase heat dissipation efficiency.

As shown in FIG. 1 and FIG. 2, the second heat dissipation fin group 112 may include a first block overlapped with the first heat dissipation fin group 111 and a second block not overlapped with the first heat dissipation fin group 111. In addition, the second block of the second heat dissipation fin group 112 is suspended above the circuit board 101. Further, the space between the second block of the second heat dissipation fin group 112 and the circuit board 101 (i.e., the peripheral space of the first heat dissipation fin group 111) may not only increase convection, but also serve as a heat dissipation space for other heat sources or electronic components adjacent to the heat source 102 or the heat dissipation member 110.

In this embodiment, since the first heat dissipation fin group 111 and the second heat dissipation fin group 112 form a double-layer heat dissipation fin group, the heat exchange area can be increased. To be specific, the fan 120 is configured to rotate around an axis AX. The airflow caused during operation of the fan 120 first flows through the second heat dissipation fin group 112, and then flows toward the first heat dissipation fin group 111 for heat to be respectively exchanged between the air flow and the second heat dissipation fin group 112 and between the air flow the first heat dissipation fin group 111. In addition, the airflow may flow to the space between the second block of the second heat dissipation fin group 112 and the circuit board 101 (i.e., the peripheral space of the first heat dissipation fin group 111), to dissipate heat from other heat sources or electronic components adjacent to the heat source 102 or the heat dissipation member 110.

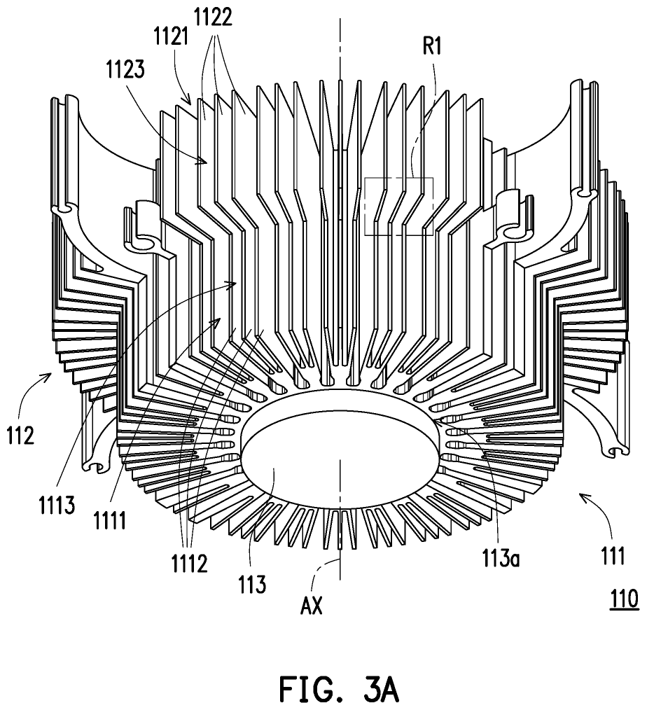

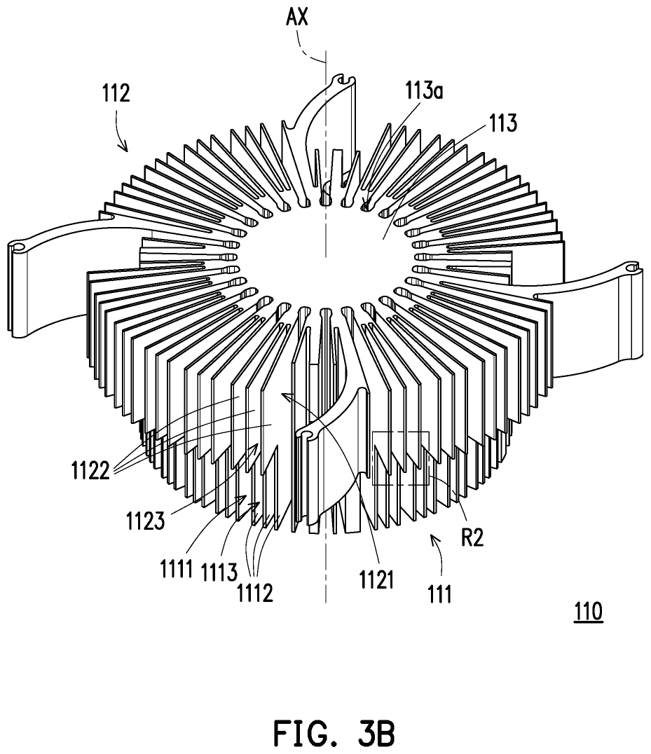

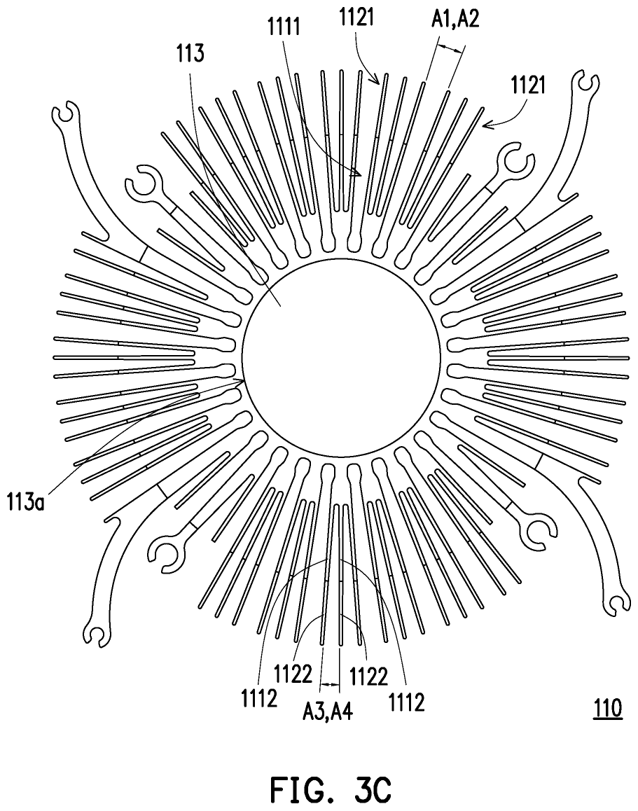

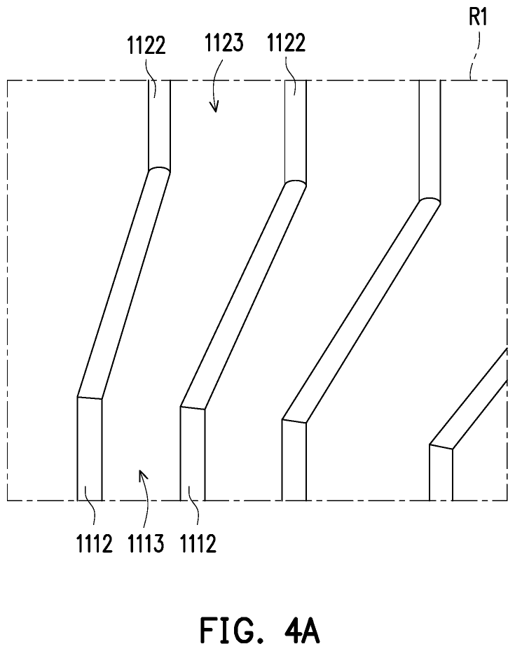

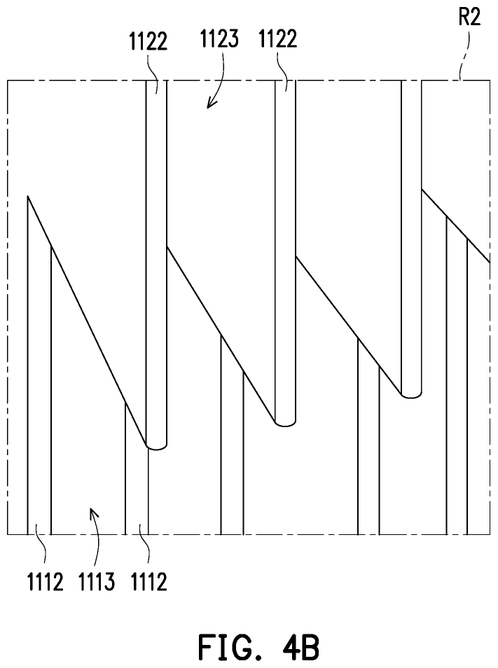

FIG. 3A to FIG. 3C are schematic views of the heat dissipation member of FIG. 2 in three different perspectives, among which FIG. 3C is illustrated from a bottom view angle. FIG. 4A is a schematic enlarged view of a region R1 of FIG. 3A. FIG. 4B is a schematic enlarged view of a region R2 of FIG. 3B. With reference to FIG. 3A to FIG. 3C, in this embodiment, the first heat dissipation fin group 111 includes a plurality of first heat dissipation fins 1111, and the first heat dissipation fins 1111 are radially arranged. Correspondingly, the second heat dissipation fin group 112 includes a plurality of second heat dissipation fins 1121, and the second heat dissipation fins 1121 are radially arranged. In addition, the number of first heat dissipation fins 1111 is equal to the number of second heat dissipation fins 1121.

For example, each first heat dissipation fin 1111 has a three-pronged structure and each second heat dissipation fin 1121 has a three-pronged structure. In addition, the size of each first heat dissipation fin 1111 is smaller than the size of each second heat dissipation fin 1121. The size of each first heat dissipation fin 1111 may refer to the volume, area, or radial length. Correspondingly, the size of each second heat dissipation fin 1121 may refer to the volume, area, or radial length. As shown in FIG. 3C, the radial length of each second heat dissipation fin 1121 is greater than the radial length of each first heat dissipation fin 1111.

With reference to FIG. 3A to FIG. 3C, the plurality of first heat dissipation fins 1111 and the plurality of second heat dissipation fins 1121 are arranged around the axis AX. In addition, a first included angle A1 between any two adjacent second heat dissipation fins 1121 is equal to a second included angle A2 between any two adjacent first heat dissipation fins 1111. On the other hand, the heat dissipation member 110 also includes a base 113. The axis AX passes through the base 113. The plurality of first heat dissipation fins 1111 and the plurality of second heat dissipation fins 1121 are formed on an outer wall surface 113a of the base 113.

As shown in FIG. 1, one end of the base 113 is thermally coupled to the heat source 102. The heat generated by the heat source 102 may be conducted through the base 113 to the first heat dissipation fin group 111 and the second heat dissipation fin group 112. As shown in FIG. 3C, since the plurality of first heat dissipation fins 1111 and the plurality of second heat dissipation fins 1121 are radially arranged, a first distance between any two adjacent first heat dissipation fins 1111 gradually increases along the radial direction in a direction away from the base 113, and a second distance between any two adjacent second heat dissipation fins 1121 gradually increases along the radial direction in the direction away from the base 113. To be specific, the change in the first distance in the radial direction is equal to the change in the second distance in the radial direction. That is, in the same circumferential direction, the first distance is equal to the second distance.

With reference to FIG. 3A to FIG. 3C, in a direction parallel to the axis AX, each first heat dissipation fin 1111 is overlapped with one corresponding second heat dissipation fin 1121, and each first heat dissipation fin 1111 is connected to the one corresponding second heat dissipation fin 1121. In the radial direction, each second heat dissipation fin 1121 includes a first segment overlapped with one corresponding first heat dissipation fin 1111 and a second segment extending beyond the corresponding first heat dissipation fin 1111. In addition, the first segment of each second heat dissipation fin 1121 is connected to the corresponding first heat dissipation fin 1111.

With reference to FIG. 3A, FIG. 3B, FIG. 4A, and FIG. 4B, each first heat dissipation fin 1111 includes a plurality of first heat dissipation branches 1112. Correspondingly, each second heat dissipation fin 1121 includes a plurality of second heat dissipation branches 1122. In addition, the number of first heat dissipation branches 1112 of each first heat dissipation fin 1111 is equal to the number of second heat dissipation branches 1122 of each second heat dissipation fin 1121. In the direction parallel to the axis AX, the plurality of first heat dissipation branches 1112 are overlapped with the plurality of second heat dissipation branches 1122, and each first heat dissipation branch 1112 is connected to the corresponding second heat dissipation branch 1122. Since each first heat dissipation branch 1112 is connected to one corresponding second heat dissipation branch 1122, each first heat dissipation branch 1112 may quickly conduct heat to the corresponding second heat dissipation branch 1122.

On the other hand, the size of each first heat dissipation branch 1112 is smaller than the size of each second heat dissipation branch 1122. The size of each first heat dissipation branch 1112 may refer to the volume, area, or radial length. Correspondingly, the size of each second heat dissipation branch 1122 may refer to the volume, area, or radial length. As shown in FIG. 3C, the radial length of each second heat dissipation branch 1122 is greater than the radial length of each first heat dissipation branch 1112.

With reference to FIG. 3A, FIG. 3B, FIG. 4A, and FIG. 4B, in the radial direction, each second heat dissipation branch 1122 includes a first segment overlapped with one corresponding first heat dissipation branch 1112 and a second segment extending beyond the corresponding first heat dissipation branch 1112. In addition, the first segment of each second heat dissipation branch 1122 is connected to the corresponding first heat dissipation branch 1112.

As shown in FIG. 3C, in any one of the first heat dissipation fins 1111 and any one of the second heat dissipation fins 1121, a third included angle A3 between any two adjacent first heat dissipation branches 1112 is equal to a fourth included angle A4 between any two adjacent second heat dissipation branches 1122. On the other hand, a third distance between any two adjacent first heat dissipation branches 1112 gradually increases along the radial direction in a direction away from the base 113, and a fourth distance between any two adjacent second heat dissipation branches 1122 gradually increases along the radial direction in the direction away from the base 113. To be specific, the change in the third distance in the radial direction is equal to the change in the fourth distance in the radial direction. That is, in the same circumferential direction, the third distance is equal to the fourth distance.

With reference to FIG. 3A to FIG. 3C, in this embodiment, the first heat dissipation fin group 111 has a plurality of first passages 1113, and the second heat dissipation fin group 112 has a plurality of second passages 1123. The number of first passages 1113 are equal to the number of second passages 1123. Any two adjacent first heat dissipation branches 1112 are spaced apart by one first passage 1113, and any two adjacent second heat dissipation branches 1122 are spaced apart by one second passage 1123. A first circumferential width of each first passage 1113 gradually increases along the radial direction in a direction away from the base 113, and a second circumferential width of each second passage 1123 gradually increases along the radial direction in the direction away from the base 113. To be specific, the change in the first circumferential width in the radial direction is equal to the change in the second circumferential width in the radial direction. That is, in the same circumferential direction, the first circumferential width is equal to the second circumferential width.

With reference to FIG. 3A, FIG. 3B, FIG. 4A, and FIG. 4B, in the direction parallel to the axis AX, each first passage 1113 is overlapped with and in communication with one second passage 1123, thus helping to improve the flow efficiency of an airflow passing through the heat dissipation member 110.

As shown in FIG. 1, FIGS. 2 and 3A, the airflow caused during operation of the fan 120 first flows through the plurality of second passages 1123, and then flows into the plurality of first passages 1113. Alternatively, the airflow flows from the plurality of second passages 1123 into the space between the second block of the second heat dissipation fin group 112 and the circuit board 101 (i.e., the peripheral space of the first heat dissipation fin group 111). When the airflow flows through any second passage 1123, heat is exchanged between the airflow and any two adjacent second heat dissipation branches 1122. In addition, each second heat dissipation branch 1122 may provide a relatively great heat exchange area. When the airflow flows through any first passage 1113, heat is exchanged between the airflow and any two adjacent first heat dissipation branches 1112.

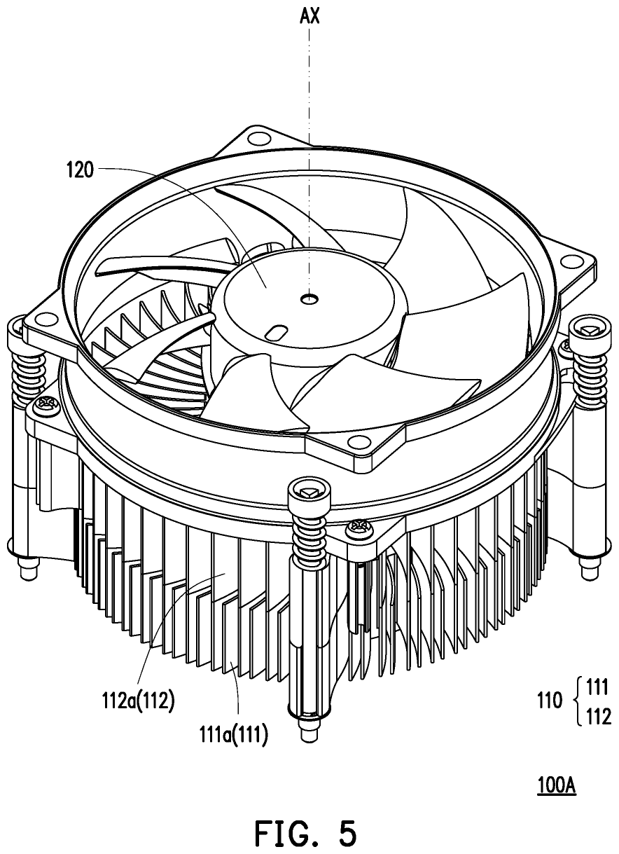

FIG. 5 is a schematic diagram of a heat dissipation device according to another embodiment of the disclosure. With reference to FIG. 5, in this embodiment, a heat dissipation device 100A may be mounted in electronic products to quickly dissipate heat generated during operation of an electronic component (e.g., a chip, a processor, or a controller) in the electronic products to the outside. To be specific, the heat dissipation device 100A adopts a double-layer heat dissipation fin group. The heat dissipation device 100A includes a heat dissipation member 110a and the fan 120, and the heat dissipation member 110a includes the first heat dissipation fin group 111 and the second heat dissipation fin group 112 stacked on the first heat dissipation fin group 111. The fan 120 is stacked on the second heat dissipation fin group 112, and the second heat dissipation fin group 112 is located between the fan 120 and the first heat dissipation fin group 111. In other words, the second heat dissipation fin group 112 is closer to the fan 120 than the first heat dissipation fin group 111 is.

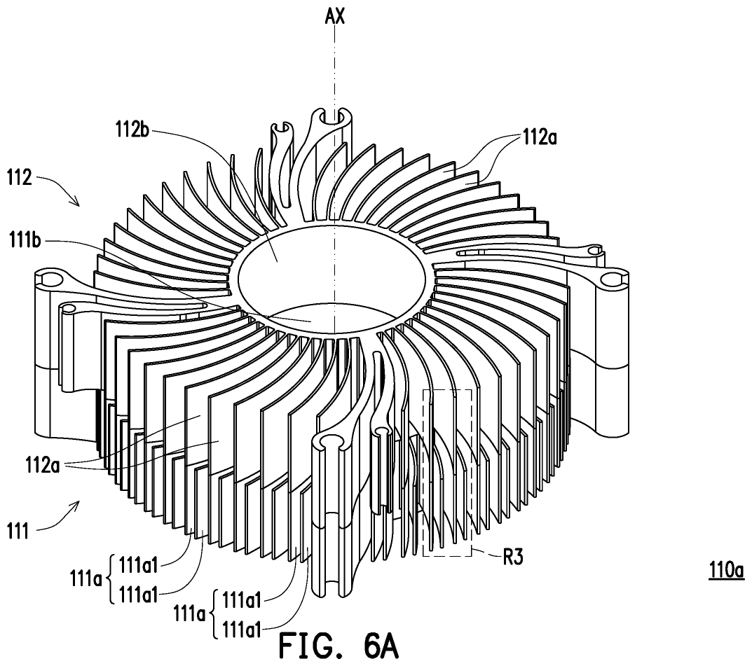

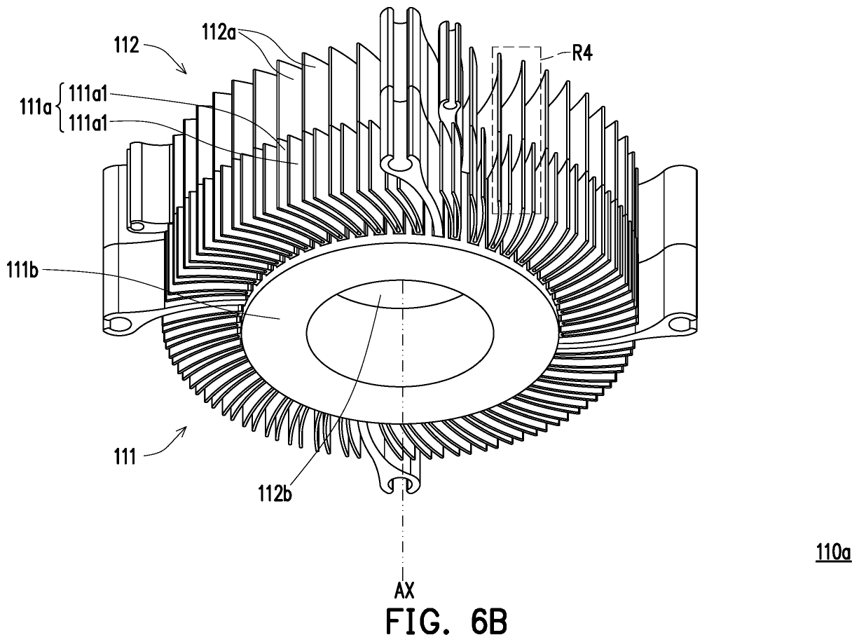

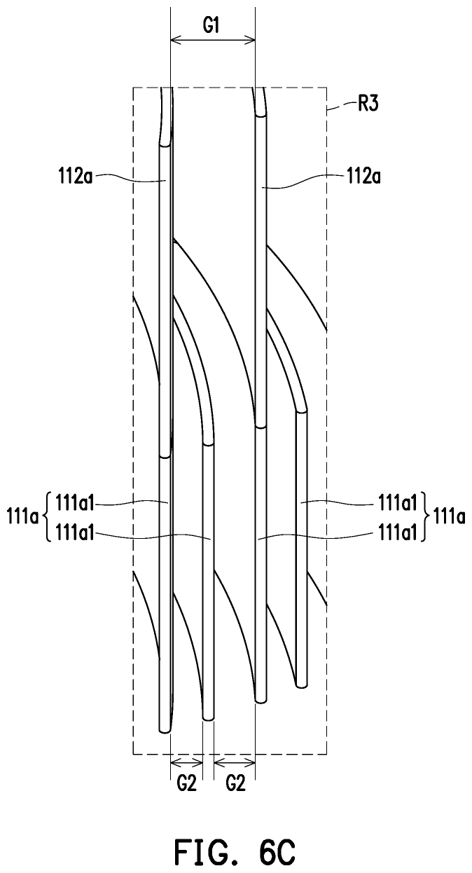

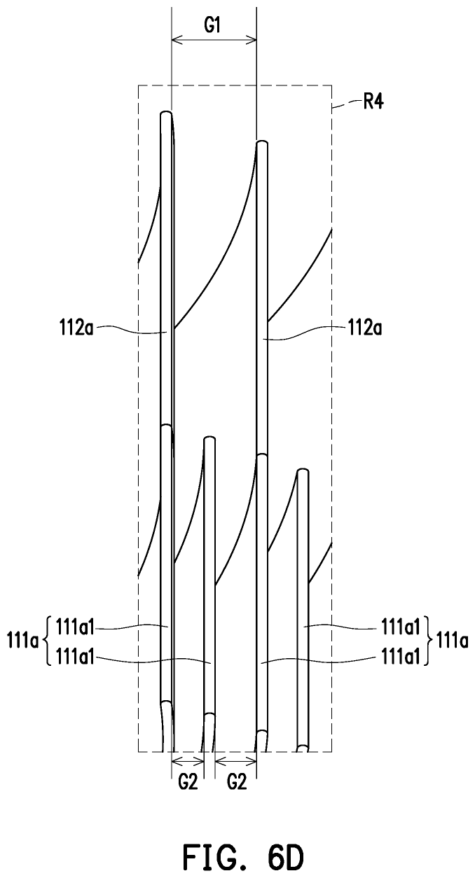

FIG. 6A and FIG. 6B are schematic views of the heat dissipation member of FIG. 5 in two different perspectives. FIG. 6C is a schematic enlarged view of a region R3 of FIG. 6A. FIG. 6D is a schematic enlarged view of a region R4 of FIG. 6B. With reference to FIG. 5, FIG. 6A, and FIG. 6B, the first heat dissipation fin group 111 and the second heat dissipation fin group 112 may be a two-stage aluminum extrusion structure, thus exhibiting the properties of great design flexibility, low manufacturing costs, light weight, and great strength. The fan 120 may adopt an axial fan and may be configured to rotate around the axis AX. The airflow caused during operation of the fan 120 first flows through the second heat dissipation fin group 112, and then flows toward the first heat dissipation fin group 111.

In this embodiment, the first heat dissipation fin group 111 includes a plurality of first heat dissipation fins 111a, and the second heat dissipation fin group 112 includes a plurality of second heat dissipation fins 112a. The plurality of first heat dissipation fins 111a and the plurality of second heat dissipation fins 112a are arranged around the axis AX. In the direction parallel to the axis AX, the fan 120 is overlapped with the plurality of second heat dissipation fins 112a and the plurality of first heat dissipation fins 111a, to ensure that the airflow caused during operation of the fan 120 successively flows through the plurality of second heat dissipation fins 112a and the plurality of first heat dissipation fins 111a for heat exchange.

Further, the plurality of first heat dissipation fins 111a are arranged equidistantly around the axis AX, and the plurality of second heat dissipation fins 112a are arranged equidistantly around the axis AX. Moreover, a distance G1 between any two adjacent second heat dissipation fins 112a is greater than a distance G2 between any two adjacent first heat dissipation fins 111a, as shown in FIG. 6C and FIG. 6D. In other words, the arrangement of the plurality of second heat dissipation fins 112a in the second heat dissipation fin group 112 is sparser than the arrangement of the plurality of first heat dissipation fins 111a in the first heat dissipation fin group 111.

Since the arrangement of the plurality of second heat dissipation fins 112a in the second heat dissipation fin group 112 is sparser than the arrangement of the plurality of first heat dissipation fins 111a in the first heat dissipation fin group 111, the second heat dissipation fin group 112 has a lower flow resistance to the airflow caused during operation of the fan 120 than the first heat dissipation fin group 111 does. Therefore, the airflow caused during operation of the fan 120 may quickly flow through the second heat dissipation fin group 112 and flow toward the first heat dissipation fin group 111. As such, the heat dissipation device 100A exhibits good flow efficiency, and the noise generated during operation of the fan 120 is reduced.

With reference to FIG. 5, FIG. 6A, and FIG. 6B, when the airflow caused during operation of the fan 120 flows to the first heat dissipation fin group 111, since the arrangement of the plurality of first heat dissipation fins 111a in the first heat dissipation fin group 111 is denser than the arrangement of the plurality of second heat dissipation fins 112a in the second heat dissipation fin group 112, the first heat dissipation fin group 111 may provide a greater heat dissipation area, such that the heat dissipation efficiency of the heat dissipation device 100A is improved.

With reference to FIG. 6A to FIG. 6D, in this embodiment, the first heat dissipation fin group 111 also includes a first base 111b, and the second heat dissipation fin group 112 also includes a second base 112b stacked on the first base 111b. In addition, the axis AX passes through the second base 112b and the first base 111b. To be specific, the plurality of first heat dissipation fins 111a are connected to the first base 111b, and are arranged on an outer wall surface of the first base 111b around the axis AX. On the other hand, the plurality of second heat dissipation fins 112a are connected to the second base 112b, and are arranged on an outer wall surface of the second base 112b around the axis AX.

The first base 111b is farther from the fan 120 than the second base 112b is, and the first base 111b is closer to the heat source than the second base 112b is. Since the size (e.g., the volume) of the first base 111b is greater than the size (e.g., the volume) of the second base 112b, the specific heat capacity of the first base 111b is greater than the specific heat capacity of the second base 112b. In other words, the first base 111b exhibits greater heat absorption and heat dissipation, helping to increase the heat dissipation efficiency.

In the direction parallel to the axis AX, part of the plurality of second heat dissipation fins 112a are overlapped with part of the plurality of first heat dissipation fins 111a. In addition, any second heat dissipation fin 112a and any first heat dissipation fin 111a that are overlapped with each other are in contact with each other. In other embodiments, any second heat dissipation fin and any first heat dissipation fin that are overlapped with each other are kept at a distance with each other in the direction parallel to the axis, and they are not in contact with each other.

In this embodiment, each first heat dissipation fin 111a includes two heat dissipation branches 111a1. In the direction parallel to the axis AX, a heat dissipation branch 111a1 is disposed between any two adjacent second heat dissipation fins 112a. That is to say, the plurality of second heat dissipation fins 112a and part of the plurality of heat dissipation branches 111a1 adopts a design in which upper and lower layers are arranged in a staggered manner to increase the heat dissipation efficiency. Furthermore, the size (e.g., the volume) of the first base 111b is greater than the size (e.g., the volume) of the second base 112b. In addition, the number of heat dissipation branches 111a1 in the first heat dissipation fin group 111 is greater than the number of second heat dissipation fins 112a in the second heat dissipation fin group 112. Therefore, the specific heat capacity of the first heat dissipation fin group 111 is greater than the specific heat capacity of the second heat dissipation fin group 112. In other words, the first heat dissipation fin group 111 exhibits greater heat absorption and heat dissipation, helping to increase the heat dissipation efficiency.

In the direction parallel to the axis AX, part of the plurality of second heat dissipation fins 112a are overlapped with part of the plurality of heat dissipation branches 111a1, and any second heat dissipation fin 112a and any heat dissipation branch 111a1 that are overlapped with each other are in contact with each other to increase the heat transfer.

In other embodiments, a gap is maintained between the second heat dissipation fin and the heat dissipation branch that are overlapped with each other in the direction parallel to the axis (i.e., the second heat dissipation fin is not in contact with the heat dissipation branch) to destroy the airflow boundary layer. In other words, the gap between the second heat dissipation fin and the heat dissipation branch forms a turbulence design to increase the heat transfer.

In particular, the distance G1 between any two adjacent second heat dissipation fins 112a is greater than the distance G2 between any two adjacent first heat dissipation fins 111a. The distance G2 may be a distance between two heat dissipation branches 111a1 in the same first heat dissipation fin 111a; alternatively, the distance G2 may be a distance between two heat dissipation branches 111a1 that belong to two different first heat dissipation fins 111a but that are adjacent, as shown in FIG. 6C and FIG. 6D.

In other embodiments, the first heat dissipation fin adopts a branchless design. That is, the first heat dissipation fin is a single heat dissipation piece, and the number of first heat dissipation fins is greater than the number of second heat dissipation fins.

In summary of the foregoing, in the heat dissipation device according to an embodiment of the disclosure, the heat dissipation member is thermally coupled to the heat source. In the heat dissipation member, since the first heat dissipation fin group is closer to the heat source than the second heat dissipation fin group is, and the size of the first heat dissipation fin group is smaller than the size of the second heat dissipation fin group, an airflow may flow in the peripheral space of the first heat dissipation fin group to enhance convection and increase heat dissipation efficiency. On the other hand, since the second heat dissipation fin group is closer to the fan than the first heat dissipation fin group is, and the size of the second heat dissipation fin group is greater than the size of the first heat dissipation fin group, the second heat dissipation fin group may provide a greater heat exchange area or heat dissipation area to increase the heat dissipation efficiency.

In the heat dissipation device according to another embodiment of the disclosure, the second heat dissipation fin group is closer to the fan than the first heat dissipation fin group is, and the arrangement of the plurality of second heat dissipation fins in the second heat dissipation fin group is sparser than the arrangement of the plurality of first heat dissipation fins in the first heat dissipation fin group. Therefore, the airflow caused during operation of the fan may quickly flow through the second heat dissipation fin group and flow toward the first heat dissipation fin group. Moreover, the first heat dissipation fin group may provide a greater heat dissipation area, thereby increasing the flow efficiency and heat dissipation efficiency.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A heat dissipation device, comprising:
a heat dissipation member, comprising a first heat dissipation fin group and a second heat dissipation fin group stacked on the first heat dissipation fin group, wherein the first heat dissipation fin group comprises a plurality of first heat dissipation fins, and the second heat dissipation fin group comprises a plurality of second heat dissipation fins; and
a fan, stacked on the second heat dissipation fin group, wherein the fan is configured to rotate around an axis, and the first heat dissipation fins and the second heat dissipation fins are arranged around the axis.

2. The heat dissipation device described in claim 1, wherein a size of the first heat dissipation fin group is smaller than a size of the second heat dissipation fin group, and an included angle between any adjacent two of the second heat dissipation fins is equal to an included angle between any adjacent two of the first heat dissipation fins.

3. The heat dissipation device described in claim 2, wherein the heat dissipation member further comprises a base, the axis passes through the base, and the first heat dissipation fins and the second heat dissipation fins are formed on an outer wall surface of the base.

4. The heat dissipation device described in claim 2, wherein a size of each of the first heat dissipation fins is smaller than a size of each of the second heat dissipation fins.

5. The heat dissipation device described in claim 2, wherein in a direction parallel to the axis, each of the first heat dissipation fins is overlapped with one of the second heat dissipation fins.

6. The heat dissipation device described in claim 2, wherein in a direction parallel to the axis, each of the first heat dissipation fins is connected to one of the second heat dissipation fins.

7. The heat dissipation device described in claim 2, wherein each of the first heat dissipation fins comprises a plurality of first heat dissipation branches, and each of the second heat dissipation fins comprises a plurality of second heat dissipation branches, wherein in a direction parallel to the axis, the first heat dissipation branches of each of the first heat dissipation fins are overlapped with the second heat dissipation branches of one of the second heat dissipation fins.

8. The heat dissipation device described in claim 7, wherein a size of each of the first heat dissipation branches is smaller than a size of each of the second heat dissipation branches.

9. The heat dissipation device described in claim 2, wherein each of the first heat dissipation fins comprises a plurality of first heat dissipation branches, and each of the second heat dissipation fins includes a plurality of second heat dissipation branches, wherein a quantity of the first heat dissipation branches of each of the first heat dissipation fins is equal to a quantity of the second heat dissipation branches of each of the second heat dissipation fins.

10. The heat dissipation device described in claim 2, wherein each of the first heat dissipation fins comprises a plurality of first heat dissipation branches, and each of the second heat dissipation fins includes a plurality of second heat dissipation branches, wherein in a direction parallel to the axis, the first heat dissipation branches of each of the first heat dissipation fins are connected to the second heat dissipation branches of one of the second heat dissipation fins.

11. The heat dissipation device described in claim 2, wherein each of the first heat dissipation fins comprises a plurality of first heat dissipation branches, and each of the second heat dissipation fins comprises a plurality of second heat dissipation branches, wherein an included angle between any adjacent two of the first heat dissipation branches in any one of the first heat dissipation fins is equal to an included angle between any adjacent two of the second heat dissipation branches in any one of the second heat dissipation fins.

12. The heat dissipation device described in claim 2, wherein the first heat dissipation fin group has a plurality of first passages, the second heat dissipation fin group has a plurality of second passages, each of the first heat dissipation fins comprises a plurality of first heat dissipation branches, and each of the second heat dissipation fins comprises a plurality of second heat dissipation branches, wherein any adjacent two of the first heat dissipation branches are spaced apart by one of the first passages, and any adjacent two of the second heat dissipation branches are spaced apart by one of the second passages.

13. The heat dissipation device described in claim 12, wherein in a direction parallel to the axis, each of the first passages is overlapped with and in communication with one of the second passages.

14. The heat dissipation device described in claim 1, wherein a distance between any adjacent two of the second heat dissipation fins is greater than a distance between any adjacent two of the first heat dissipation fins.

15. The heat dissipation device described in claim 14, wherein the first heat dissipation fin group further comprises a first base, the second heat dissipation fin group further comprises a second base stacked on the first base, and the axis passes through the second base and the first base.

16. The heat dissipation device described in claim 15, wherein the first heat dissipation fins are connected to the first base, and the second heat dissipation fins are connected to the second base.

17. The heat dissipation device described in claim 16, wherein a size of the first base is greater than a size of the second base.

18. The heat dissipation device described in claim 14, wherein each of the first heat dissipation fins comprises two heat dissipation branches, and in a direction parallel to the axis, one of the heat dissipation branches is disposed between any adjacent two of the second heat dissipation fins.

19. The heat dissipation device described in claim 18, wherein in the direction parallel to the axis, part of the second heat dissipation fins are overlapped with part of the heat dissipation branches.

20. The heat dissipation device described in claim 18, wherein in the direction parallel to the axis, part of the second heat dissipation fins are in contact with part of the heat dissipation branches.

21. The heat dissipation device described in claim 14, wherein in a direction parallel to the axis, part of the second heat dissipation fins are overlapped with part of the first heat dissipation fins.

22. The heat dissipation device described in claim 14, wherein in a direction parallel to the axis, part of the second heat dissipation fins are in contact with part of the first heat dissipation fins.

23. The heat dissipation device described in claim 14, wherein the first heat dissipation fins are arranged equidistantly around the axis, and the second heat dissipation fins are arranged equidistantly around the axis.

24. The heat dissipation device described in claim 14, wherein the first heat dissipation fin group and the second heat dissipation fin group are a two-stage aluminum extrusion structure.
